(19) United States
(12) Patent Application Publication
(10) Pub. No.: US 2025/0391747 A1
(43) Pub. Date: Dec. 25, 2025

(54) METHOD OF FORMING A DIE PACKAGE AND DIE PACKAGE ARRANGEMENT

(71) Applicant: Infineon Technologies AG, Neubiberg (DE)

(72) Inventors: Michael Reyes GODOY, Muar (MY); Dominic Carlos ANONUEVO, Melaka (MY); Muhammad Asyraf RAMLI, Melaka (MY)

(73) Assignee: Infineon Technologies AG, Neubiberg (DE)

(21) Appl. No.: 19/241,484

(22) Filed: Jun. 18, 2025

(30) Foreign Application Priority Data
Jun. 25, 2024 (DE) 10 2024 117 799.3

(51) Int. Cl. H01L 23/495; C25D 7/12; H01L 21/56; H01L 23/00

(52) U.S. Cl. CPC H01L 23/49551; C25D 7/12; H01L 21/56; H01L 23/49582; H01L 24/40; H01L 24/84; H01L 2224/40245; H01L 2224/84201; H01L 2224/8492

(57) ABSTRACT

A method of forming a die package is provided. The method includes attaching a die to a leadframe, attaching a clip to the die, wherein the clip includes a leadframe contact section that is arranged adjacent to a corresponding clip contact section of the leadframe, and deforming the clip contact section of the leadframe and/or the leadframe contact section of the clip to form a fixed electrically conductive contact between the leadframe and the clip.

### CROSS-REFERENCE TO RELATED APPLICATION

This Utility Patent application claims priority to German Patent Application No. 10 2024 117 799.3 filed Jun. 25, 2024, which is incorporated herein by reference.

### TECHNICAL FIELD

Various embodiments relate generally to a method of forming a die package and die package arrangement.

### BACKGROUND

A leadframe and/or clip used in a semiconductor package or parts thereof are typically plated with a suitable material in order to achieve desirable characteristics such as improved solderability, adhesion and/or corrosion resistance. Examples of common plating materials include tin, silver or alloys (Nickle-palladium-gold). However, it has been observed during die package manufacture that that some or all parts of a clip may remain unplated at the end of a plating process. Incomplete plating is undesirable for example, when a clip includes an integrated lead portion which is configured to make electrical contact externally. This is because the beneficial characteristics associated with a plated clip or lead such as improved solderability and corrosion resistance are not achieved. As a result, the respective die package has to be rejected. In view of the foregoing, it is desirable to mitigate the problem of unplated or underplated clips occurring during the semiconductor packaging process.

### SUMMARY

A plating process typically involves immersing a die, leadframe and clip assembly in a plating solution and applying a current to the leadframe. The electroplating current will flow from the leadframe to the clip causing a reaction with the plating solution and the clip to be plated as well. The inventors have discovered that some or all parts of a clip can be left unplated when there is no or inconsistent electrically conductive contact between a clip and a leadframe during the plating process resulting in insufficient current flow from the leadframe to the clip.

A method of forming a die package is provided. The method includes attaching a die to a leadframe, attaching a clip to the die, wherein the clip includes a leadframe contact section that is arranged adjacent to a corresponding clip contact section of the leadframe, and deforming the clip contact section of the leadframe and/or the leadframe contact section of the clip to form a fixed electrically conductive contact between the leadframe and the clip.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a flow diagram of a method of forming a die package in accordance with various embodiments;

FIG. 2 shows a schematic diagram of a die package arrangement before applying a pinching process of a method of forming a die package in accordance with various embodiments;

FIG. 3 illustrates in several schematic drawings a pinching process of a method of forming a die package in accordance with various embodiments;

FIG. 4 illustrates a pinching tool applying a pinching process of a method of forming a die package in accordance with various embodiments;

FIG. 5 shows schematic drawings of a deformed portion formed by a pinching process of a method of forming a die package in accordance with various embodiments;

FIG. 6 shows a flow diagram of a method of forming a die package in accordance with various embodiments;

FIG. 7 shows a schematic diagram of a die package arrangement in accordance with various embodiments;

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In a die package, a leadframe may be attached to a bottom side of a die, and a clip may be attached to a top side of a die. In some manufacturing processes, the clip comprises a leadframe contact section and the leadframe a corresponding clip contact section. The leadframe and clip contact sections may be specifically provided for allowing current to flow from the leadframe to the clip during the electroplating process. In some cases, however, there may be a gap between the clip and the leadframe thus resulting in incomplete or no plating. Such separation may take the form of a vertical distance (with planes of the leadframe and the clip, respectively being defined as horizontal) and may occur due to manufacturing tolerances in the clip/leadframe or shifts in the relative positions of the leadframe and clip during the packaging process.

As a present solution, a clip is soldered to the leadframe in order to provide a fixed electrical contact between the leadframe and the clip during the plating process. By way of example, the clip may be soldered to the leadframe at positions located within a section of the leadframe which will be removed from the final package. However, this solution has its drawbacks as the solder material will contaminate the plating bath thus requiring frequent plating bath changes. This in turn results in increased plating chemical cost and equipment downtime.

In various embodiments, a reliable, e.g., fixed, electrically conductive contact is provided between a clip and a leadframe by deforming the clip contact section of the leadframe and/or the leadframe contact section of the clip to form a fixed electrically conductive contact between the leadframe and the clip in a phase where both, the leadframe and the clip, are part of a die package arrangement and supposed to be attached to each other for providing a plating current through the leadframe to the clip.

Thereby, an occurrence of incomplete plating on leads may be eliminated.

In various embodiments, a pinching process (which may for example also be described as a binding, punching, deforming, or stamping process) may be applied to the leadframe and/or the clip, e.g., a binding punch that may deform a clip contact section of the leadframe (such as a Z stopper) to have a fixed contact to the clip. Alternatively or additionally, a leadframe contact section of the clip may be deformed to have contact to the leadframe.

In order to ensure that there is constant current flow from the leadframe to the clip during the plating process the clip contact section and/or leadframe contact section is deformed to form a fixed electrically conductive contact between the leadframe and the clip prior to plating. For avoidance of doubt, it is not essential for the fixed electrically conductive contact between the leadframe and the clip to be permanent. A temporary fixture may also be suitable so long as there is a fixed electrically conductive contact during the plating process. In various embodiments, plating may also be executed after a dambar cut. In some variants, a subsequent singulation process may singulate the individual die packages from the die package arrangement and remove, amongst others, the respective contact sections of the leadframe and the clip.

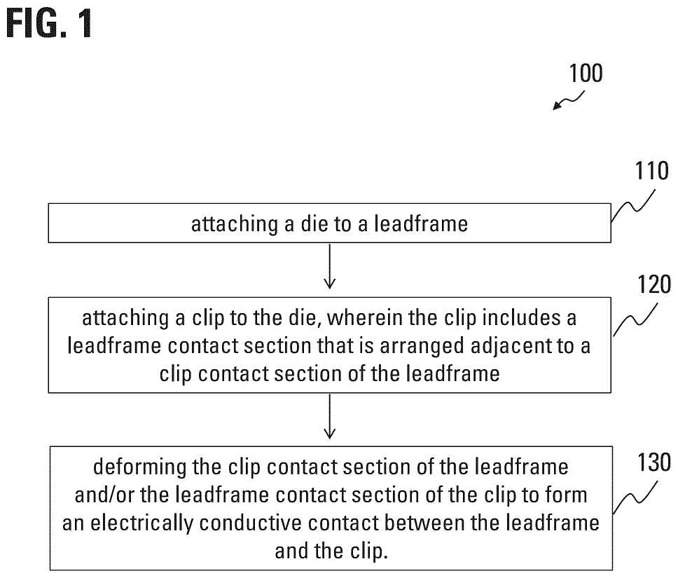

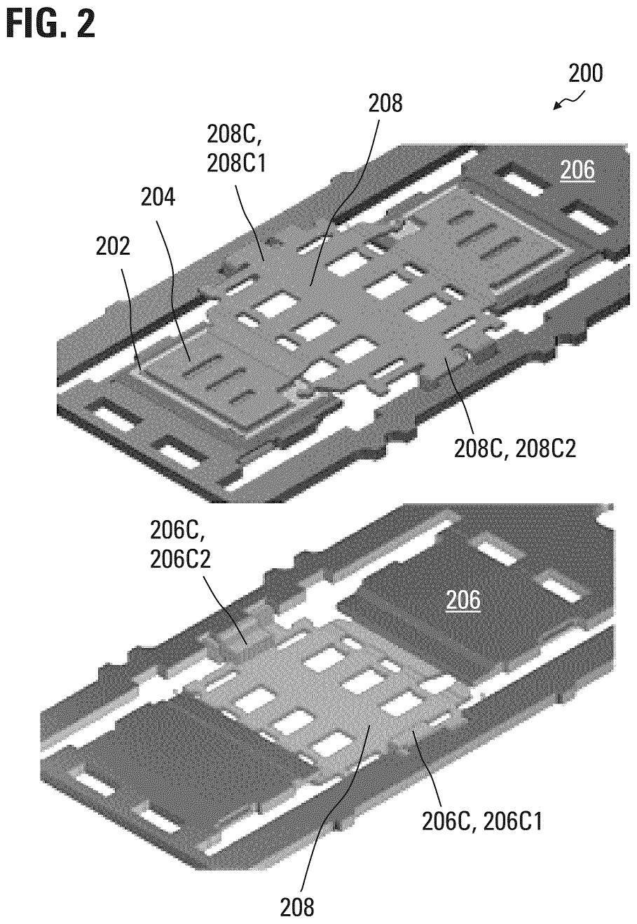

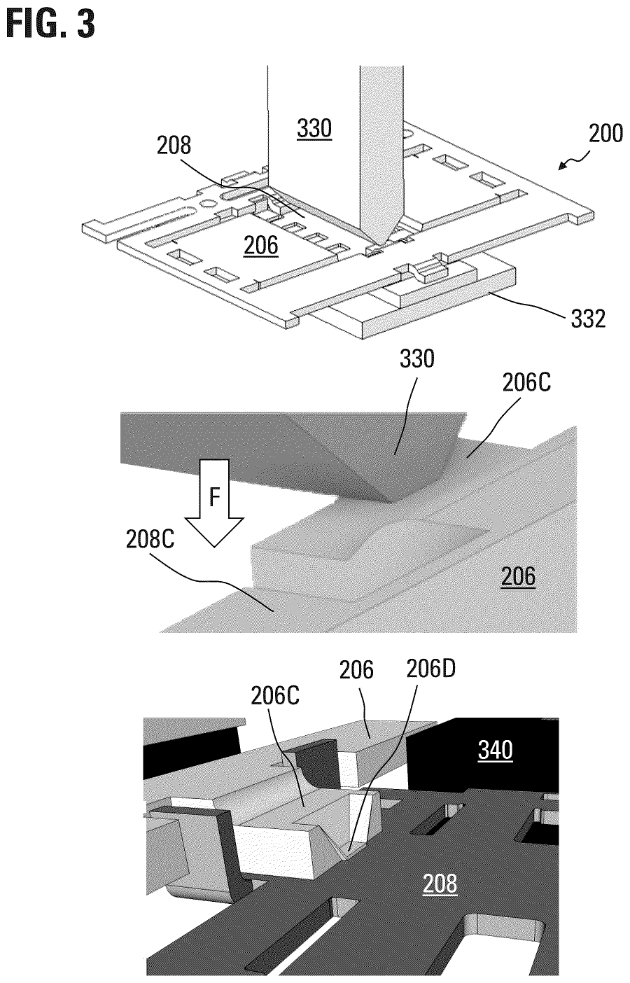

FIG. 1 shows a flow diagram 100 of a method of forming a die package 700 in accordance with various embodiments, FIG. 3 illustrates a pinching process of the method, and FIG. 2 illustrates a die package arrangement 200 before the pinching process is applied.

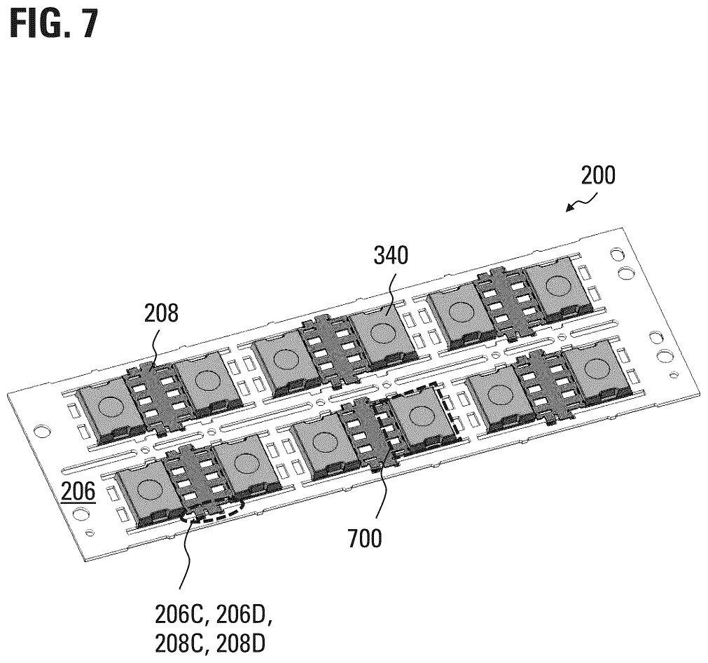

The method includes attaching a die 202 to a leadframe 206 (110) and attaching a clip 208 to the die 202. The process of attaching the die 202 to the leadframe 206 and to the clip 208 may be similar or identical to the process known in the art. For example, the die 202 may be attached with its bottom side, for example with a die contact pad (e.g., a drain pad) to the leadframe 206 to form an electrically conductive connection, for example by soldering or using an electrically conductive adhesive. The clip 208 may for example be attached to a top side of one or more dies 202. In the exemplary die package 200 arrangement of FIG. 2, the clip 208 is attached to the top side of two dies 202 but it may also be attached to the top side of only one die or more than two dies. In the FIG. 2 example, the top side of the die 202 may include a source pad and a control pad, wherein the control pad is shown to be contacted by a single lead of the clip 208, to form an electrically conductive connection, for example by soldering or using an electrically conductive adhesive. Thus, the die 202 may be sandwiched between the leadframe 206 and the clip 208, thus only a small edge and a portion around the control pad are visible in FIG. 2 (and this is only possible because a mold encapsulating the die 202 and partially encapsulating the clip 208 and the leadframe 206 is omitted). For production efficiency, as is common in the art, the die package arrangement 200 may include a plurality of die packages 700 (FIG. 7, which shows the die package arrangement 200 before the singulation of the die packages 700, indicates with a hashed line the approximate outline of one of the die packages 700). All the die packages 200 may be joined by the leadframe 206, and in this exemplary embodiment, the die packages 200 may be joined pairwise by the clips 208.

In standard die package production, electroplating of the clip 208 and the leadframe 206 is performed on the die package arrangement 200 as a more or less final process before the singulation of the die packages 700.

Since the leadframe 206 and the clip 208 are to be electroplated in a common process, even though they are configured to provide separate external contacts to the chip 202 and are therefore, in the final die package 700, not in contact with each other, an electrical contact between the leadframe 206 and the clip 208 is supposed to be provided in an area of the leadframe 206 and the clip 208 that is to be removed during singulation.

A clip contact section 206C may be part of the leadframe 206 and be intended to be contacted by a leadframe contact section 208C of the clip 208.

Since an intended contact surface of the clip contact section 206C of the leadframe 206 (in the lower image of the die package arrangement 200, which shows a bottom side of the die package arrangement 200, this would be a lower surface of the clip contact sections 206C1, 206C2, respectively) may need to be finely adjusted in its vertical positon (where a main plane of the clip 208 and the leadframe 206, respectively, define horizontal planes), such as not to impair a contacting of the die 202 by the clip 208, it may happen in die package arrangements of the prior art that in some cases an electrically conductive contact between the leadframe 206 and the clip 208 is not achieved, which means that the electroplating current, which is provided through the leadframe 206, does not reach the clip 20, which means that respective clip 208 is not electroplated and the resulting die packages 700 that have unplated leads need to be rejected.

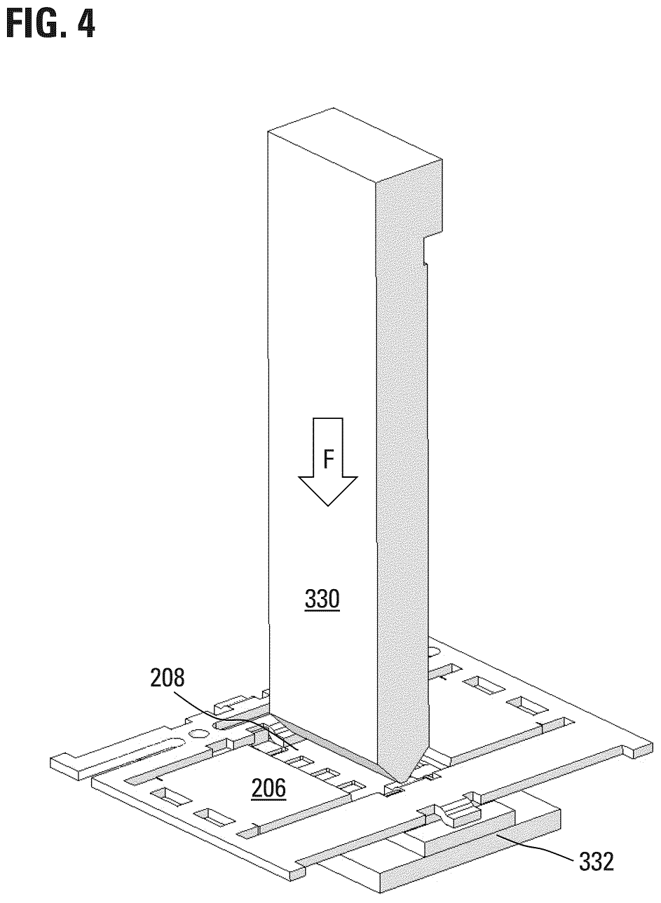

In order to ensure the electrically conductive connection between the leadframe 206 and the clip 208, the clip contact section 206C of the leadframe 206 and/or the leadframe contact section 208C of the clip is deformed to provide a fixed contact between the leadframe 206 and the clip 208. For example, the deformation process may be applied to mechanically contact, e.g. lock, each of the clips 208 of the die package arrangement 200 to the leadframe 206. Since a stamp or punching tool 330, which is shown in FIGS. 3 and 4, is used for the process to deform a portion of the leadframe 206 and/or of the clip 208 for binding/interlocking the leadframe 206 and the clip 208, the process may also be described as a stamping, punching, deforming, binding, or interlocking process, or by any other term that is suitable for describing the manipulation of the die package arrangement 200.

In various embodiments, the method further includes arranging a leadframe contact section 208C of a clip 208 adjacent (e.g., at least in a vertical direction) to a clip contact section 206C of the leadframe 206. As outlined above, the (vertically) adjacent arrangement of the leadframe contact section 208C and the clip contact section 206C may be automatically be achieved through the design of the clip 208 and the leadframe 208 when the clip 208 is attached to the die 202. As shown in FIGS. 3 and 4, the clip contact section 206C may take the form of a projection that is configured to fit into a mating recess in the leadframe contact section 208C of the clip.

In various embodiments, the method further includes deforming the clip contact section 206C of the leadframe 206 and/or the leadframe contact section 208C of the clip 208 to form a fixed electrically conductive contact between the leadframe 206 and the clip 208. In the exemplary embodiment of FIG. 3, the clip contact section 206C of the leadframe may be deformed by supporting it on support tool 332 such as a die and arranging a punch 330 over and in contact with the clip contact section 206C of the leadframe 206. A force F is applied to the punch 330 in a direction towards the clip 208 (in FIG. 3: downwards, see middle panel of FIG. 3) for deforming the clip contact section 206C of the leadframe 206. The force of the stamping action forms an indentation in the in the clip contact section 206C and pushes the leadframe material laterally outwards. The bottom panel (from a different viewing angle to better visualize the deformation) shows the resulting deformed portion 206D of the leadframe 206, which protrudes towards the clip 208, thereby at least partially mechanically interlocking the leadframe 208 and the clip 208 to form a fixed electrically conductive connection.

Therefore, subsequently, the leadframe 206 and the clip 208 may be reliably electroplated, since the current applied to the leadframe 206 is ensured to flow through the deformed portions of the clip contact section 206C and the leadframe contact section 208C, respectively, to the clip 208.

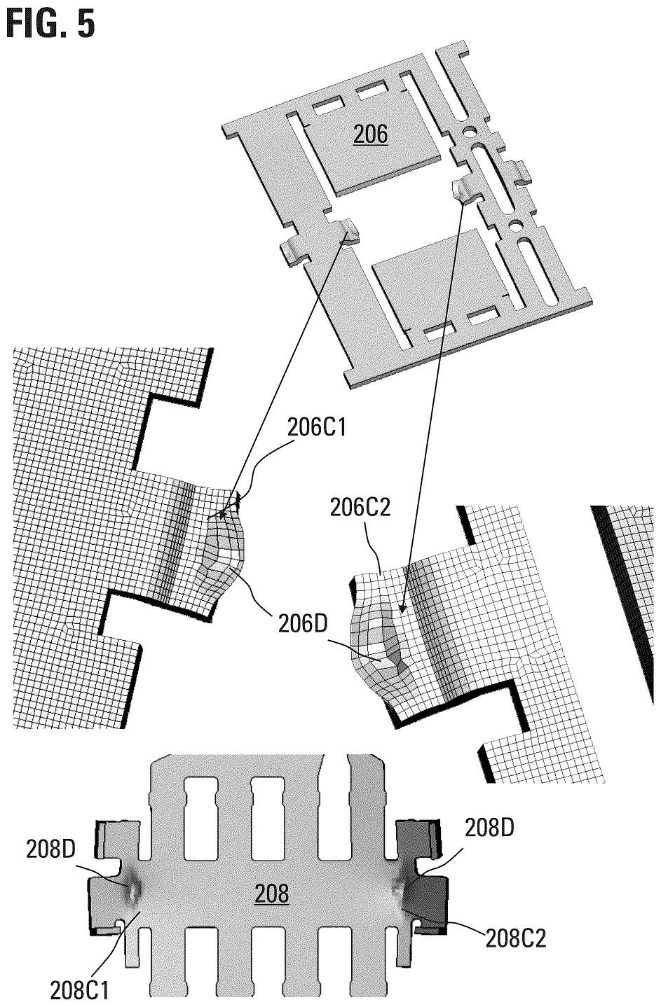

FIG. 5 shows, in simulation results, the deformed portion 206D of the leadframe 206 that results from the stamping process illustrated in FIG. 3, where the punch 330 is in contact with the clip contact section 206C of the leadframe 206.

From FIG. 5, it is clear the deforming pushes a portion 206D of the clip contact section 206C (each of the clip contact sections 206C1, 206C2) below a plane defined by a surface of the leadframe contact section 208C that faces the clip contact section 206C, since the clip 208 shown in the bottom panel has deformed portions 208D in its leadframe contact sections 208C (each of the leadframe contact sections 208C1, 208C2) that result from the deformed portions 206D being pressed into the leadframe contact sections 208C1, 208C2 of the clip 208. The deformed portion 206D of the leadframe 206 partially residing in the clip 208 provides a certain amount of mechanical interlock that secures the electrical contact.

FIG. 3 illustrates the exemplary embodiment that the deforming includes pressing a portion of the clip contact section 206C towards the clip 208, with the die package arrangement 208 being rested on a support tool 332 that keeps the die package arrangement 200 in a fixed position while the punch 330 applies the force F to deform the leadframe 206 (and the clip 208).

In various embodiments, the punch 330 may instead be arranged to directly contact and deform the clip 208 by applying the force F while the die package arrangement 200 is kept in a fixed position. In that case the deforming may push a portion of the leadframe contact section 208C below a plane defined by a surface of the clip contact section 206C that faces the leadframe contact section 208C. In other embodiments, a similar stamping process may also be applied to a leadframe contact section 208C of a clip instead or both the clip and leadframe contact sections.

In various embodiments, instead of a single punch 330, a set of stamps 330 may be arranged to apply forces from both sides, e.g., directly onto the clip 208 and the leadframe 206. Such an arrangement may for example be used in a case where respective pinching surfaces of a top- and a bottom stamp 330 are for example shaped as a positive and a negative matching set, with at least one protrusion of the top stamp 330 matching at least one cavity in the bottom stamp, or vice versa. This may allow to push respective portions of the leadframe 206 below a surface plane of the clip 208, and vice versa.

As shown in the exemplary embodiment of FIG. 3 (top panel), the leadframe contact section 208C may includes a first part 208C1 and a second part 208C2 that is separate from the first part 208C1. Similarly, the clip contact section 206C may include a first part 206C1 and a second part 206C2 that is separate from the first part 206C1.

The first part 208C1 of the leadframe contact section 208C may be arranged adjacent to the first part 206C1 of the clip contact section 206C, and the second part 206C2 of the clip contact section 206C may be arranged adjacent to the second part 208C2 of the leadframe contact section 208C.

The deforming the clip contact section 206C of the leadframe 206 and/or the leadframe contact section 208C of the clip 208 may therefore include deforming, e.g., simultaneously in a common process, e.g., by a single tool 330, both contact sections, i.e., deforming the first part 208C1 of the leadframe contact section 208C and/or the first part 206C1 of the clip contact section 206C and/or deforming the second part 208C2 of the leadframe contact section 208C and/or the second part 206C2 of the clip contact section 206C.

In other words, the first part 208C1 of the leadframe contact section 208C and the first part 206C1 of the clip contact section 206C may form a first pair, and the second part 208C2 of the leadframe contact section 208C and the second part 206C2 of the clip contact section 206C may form a second pair, and the deforming in the first pair may be performed simultaneously with the deforming in the second pair.

In various embodiments, the first part 208C1 of the leadframe contact section 208C and the second part 208C2 of the leadframe contact section 208C may be arranged on opposite sides of an opening in the leadframe 206, which may allow for a continuous and thus simple design of the tool 330. In a case where a portion of the leadframe 206 is arranged between the first part 208C1 of the leadframe contact section 208C and the second part 208C2 or where the tool 330 is arranged to press onto the clip 208, the tool 330 design may be suitably adjusted, for example by providing protrusions for applying the deforming force F.

As briefly explained above, the method may further include, after the electroplating, removing the leadframe contact section 208C of the clip 208 and the clip contact section 206C of the leadframe 206, for example by applying a singulation process.

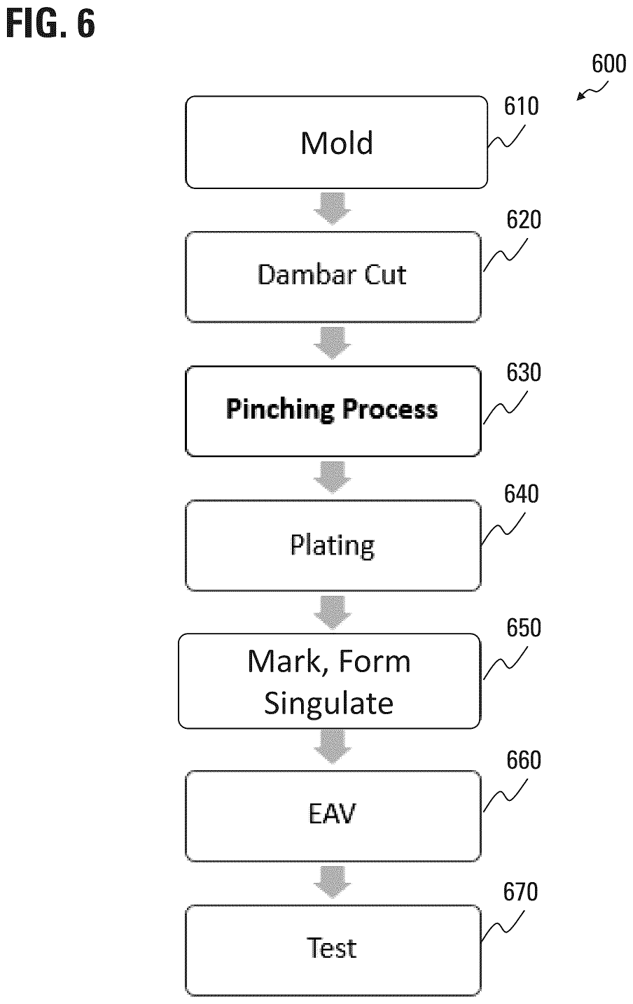

FIG. 6 shows a flow diagram 600 of a method of forming a die package in accordance with various embodiments.

The flow diagram 600 illustrates at which point in the die package production process of various embodiments the pinching process is executed.

The method of forming the die package 700 may include, as briefly outlined above, encapsulating the die 220 and at least partially encapsulating the leadframe 206 and/or the clip 208 with a molding material 340 (610).

Subsequently, a dambar cut may be applied (620), which may remove a portion of the leadframe 206 that may have been provided for restricting a flow of the molding material 340 and which may be obsolete after the molding process.

After this, the above described pinching process may be applied (630), followed by the (electro-) plating process (640).

In various embodiments, the pinching process may be performed at a different point in the process, for example before the molding and/or before the dambar cut, as long as it is performed after the attaching of the clip and before the plating. Experiments have shown that the deformation and stress introduced through the pinching process affects largely only the deformed portions 206D, 208D, with negligible stress on other areas of the die package arrangement 200. It may nevertheless increase a stability of the respective connections of the clip 208 and the leadframe 206 to the die 202 if the molding process (610) is executed before the pinching process (630).

In various embodiments, the forming the die package 700 may by finalized by marking the die packages 700 and singulating the die packages 700 from the die package arrangement 200 (e.g., along a line as outlined in FIG. 7, discarding the portions of the leadframe 206 and the clip 208 that are arranged between the die packages 700), End-Of-Line Automatic Vision (EAV) which is a form of automated visual inspection (660), and testing (670).

Various examples will be illustrated in the following:
Example 1 is a method of forming a die package. The method includes attaching a die to a leadframe, attaching a clip to the die, wherein the clip includes a leadframe contact section that is arranged adjacent to a corresponding clip contact section of the leadframe, and deforming the clip contact section of the leadframe and/or the leadframe contact section of the clip to form a fixed electrically conductive contact between the leadframe and the clip.
In Example 2, the subject-matter of Example 1 may optionally further include electroplating the leadframe and the clip after the deforming the clip contact section of the leadframe and/or the leadframe contact section of the clip.
In Example 3, the subject-matter of Example 2 may optionally further include, after the electroplating, removing the leadframe contact section of the clip and the clip contact section of the leadframe.
In Example 4, the subject-matter of any of Examples 1 to 3 may optionally include that the deforming includes pressing a portion of the clip contact section towards the clip, pressing a portion of the leadframe contact section towards the leadframe, or pressing the portion of the clip contact section and the portion of the leadframe contact section towards each other.
In Example 5, the subject-matter of any of Examples 1 to 4 may optionally include that the leadframe contact section includes a first part and a second part that is separate from the first part, that the clip contact section includes a first part and a second part that is separate from the first part, that the first part of the leadframe contact section is arranged adjacent to the first part of the clip contact section, and that the second part of the clip contact section is arranged adjacent to the second part of the leadframe contact section.
In Example 6, the subject-matter of Example 5 may optionally include that the deforming the clip contact section of the leadframe and/or the leadframe contact section of the clip includes deforming the first part of the leadframe contact section and/or the first part of the clip contact section and/or deforming the second part of the leadframe contact section and/or the second part of the clip contact section.
In Example 7, the subject-matter of Example 6 may optionally include that the first part of the leadframe contact section and the first part of the clip contact section form a first pair, and the second part of the leadframe contact section and the second part of the clip contact section form a second pair, and wherein the deformed portion in the first pair is performed simultaneously with the deformed portion in the second pair.
In Example 8, the subject-matter of Example 6 or 7 may optionally include that the first part of the leadframe contact section and the second part of the leadframe contact section are arranged on opposite sides of an opening in the leadframe.
In Example 9, the subject-matter of Example 7 or 8 may optionally include that the deformed portion in the first pair and the deformed portion in the second pair are obtained by pressing a tool that extends from the first pair to the second pair onto both, the first pair and the second pair.
In Example 10, the subject-matter of any of Examples 2 to 9 may optionally include that the current for electroplating the clip is applied through electrically conductive contact between the leadframe and the clip.
In Example 11, the subject-matter of any of Examples 1 to 10 may optionally include that the deforming is performed after the attaching the clip to the die.
In Example 12, the subject-matter of any of Examples 1 to 11 may optionally further include at least partially encapsulating the die, the clip, and the leadframe, wherein the deforming is performed after the encapsulating.
In Example 13, the subject-matter of any of Examples 1 to 12 may optionally include that the deforming pushes a portion of the clip contact section below a plane defined by a surface of the leadframe contact section that faces the clip contact section, or that the deforming pushes a portion of the leadframe contact section below a plane defined by a surface of the clip contact section that faces the leadframe contact section.
In Example 14, the subject-matter of any of Examples 1 to 13 may optionally include that the clip contact section and the leadframe contact section directly contact each other.
In Example 15, the subject-matter of any of Examples 1 to 14 may optionally include that forming an electrically conductive connection between the leadframe and the clip comprises deforming the clip engagement section and/or the leadframe engagement section such that there is an interference fit between the clip engagement section and the leadframe engagement section
Example 16 is a die package arrangement. The die package arrangement includes a die, a leadframe, wherein the die is attached to the leadframe and the leadframe includes a clip contact section, a clip attached to the die, wherein the clip includes a leadframe contact section, wherein the clip contact section of the leadframe includes a deformed portion that protrudes from the clip contact section towards the clip to form a fixed electrically conductive contact between the leadframe and the clip, and/or wherein the leadframe contact section of the clip includes a deformed portion that protrudes from the leadframe contact section towards the leadframe to form a fixed electrically conductive contact between the leadframe and the clip.
In Example 17, the subject-matter of Example 16 may optionally include that the leadframe and the clip include an electroplating layer that was applied to the assembled die package arrangement.
In Example 18, the subject-matter of Example 16 or 17 may optionally include that the clip contact section includes a portion that protrudes towards the clip, and/or the leadframe contact section includes a portion that protrudes towards the leadframe.
In Example 19, the subject-matter of any of Examples 16 to 18 may optionally include that the leadframe contact section includes a first part and a second part that is separate from the first part, that the clip contact section includes a first part and a second part that is separate from the first part, that each of the first part of the leadframe contact section and the second part of the leadframe contact section includes the protrusion to be in contact with the first part of the clip contact section and the second part of the clip contact section, respectively, or that each of the first part of the clip contact section and the second part of the clip contact section includes the protrusion to be in contact with the first part of the leadframe contact section and the second part of the leadframe contact section, respectively.
In Example 20, the subject-matter of Example 19 may optionally include that the first part of the leadframe contact section and the second part of the leadframe contact section are arranged on opposite sides of an opening in the leadframe.
In Example 21, the subject-matter of Example 19 or 20 may optionally include that the deformed portion, opposite the protrusion, is shaped as an imprint of a deformation tool.
In Example 22, the subject-matter of any of Examples 16 to 21 may optionally include that the electrically conductive contact between the leadframe and the clip is configured to apply a current for electroplating the clip and the leadframe.
In Example 23, the subject-matter of any of Examples 16 to 22 may optionally further include molding material at least partially encapsulating the die, the leadframe, and the clip, wherein the electrically conductive contact between the leadframe and the clip is free from the molding material.
In Example 24, the subject-matter of any of Examples 16 to 23 may optionally include that a portion of the clip contact section is arranged below a plane defined by a surface of the leadframe contact section that faces the clip contact section, or that a portion of the leadframe contact section is arranged below a plane defined by a surface of the clip contact section that faces the leadframe contact section.
In Example 25, the subject-matter of any of Examples 16 to 24 may optionally include that the clip contact section and the leadframe contact section directly contact each other.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of forming a die package, the method comprising:
attaching a die to a leadframe;
attaching a clip to the die, wherein the clip comprises a leadframe contact section that is arranged adjacent to a corresponding clip contact section of the leadframe; and
deforming the clip contact section of the leadframe and/or the leadframe contact section of the clip to form a fixed electrically conductive contact between the leadframe and the clip.

2. The method of claim 1, further comprising:
electroplating the leadframe and the clip after the deforming the clip contact section of the leadframe and/or the leadframe contact section of the clip.

3. The method of claim 2, further comprising:
after the electroplating, removing the leadframe contact section of the clip and the clip contact section of the leadframe.

4. The method of claim 1,
wherein the deforming comprises pressing a portion of the clip contact section towards the clip, pressing a portion of the leadframe contact section towards the leadframe, or pressing the portion of the clip contact section and the portion of the leadframe contact section towards each other.

5. The method of claim 1,
wherein the leadframe contact section comprises a first part and a second part that is separate from the first part;
wherein the clip contact section comprises a first part and a second part that is separate from the first part;
wherein the first part of the leadframe contact section is arranged adjacent to the first part of the clip contact section; and
wherein the second part of the clip contact section is arranged adjacent to the second part of the leadframe contact section.

6. The method of claim 5,
wherein the deforming the clip contact section of the leadframe and/or the leadframe contact section of the clip comprises deforming the first part of the leadframe contact section and/or the first part of the clip contact section and/or deforming the second part of the leadframe contact section and/or the second part of the clip contact section.

7. The method of claim 6,
wherein the first part of the leadframe contact section and the first part of the clip contact section form a first pair, and the second part of the leadframe contact section and the second part of the clip contact section form a second pair, and wherein the deformed portion in the first pair is performed simultaneously with the deformed portion in the second pair.

8. The method of claim 6,
wherein the first part of the leadframe contact section and the second part of the leadframe contact section are arranged on opposite sides of an opening in the leadframe.

9. The method of claim 7,
wherein deformed portion in the first pair and the deformed portion in the second pair are obtained by pressing a tool that extends from the first pair to the second pair onto both, the first pair and the second pair.

10. The method of claim 2,
wherein the current for electroplating the clip is applied through electrically conductive contact between the leadframe and the clip.

11. The method of claim 1,
wherein the deforming is performed after the attaching the clip to the die.

12. The method of claim 1, further comprising:
at least partially encapsulating the die, the clip, and the leadframe,
wherein the deforming is performed after the encapsulating.

13. The method of claim 1,
wherein the deforming pushes a portion of the clip contact section below a plane defined by a surface of the leadframe contact section that faces the clip contact section; or
wherein the deforming pushes a portion of the leadframe contact section below a plane defined by a surface of the clip contact section that faces the leadframe contact section.

14. The method of claim 1,
wherein forming an electrically conductive connection between the leadframe and the clip comprises deforming the clip engagement section and/or the leadframe engagement section such that there is an interference fit between the clip engagement section and the leadframe engagement section.

15. A die package arrangement, comprising:
a die;
a leadframe, wherein the die is attached to the leadframe and the leadframe comprises a clip contact section;
a clip attached to the die, wherein the clip comprises a leadframe contact section;
wherein the clip contact section of the leadframe comprises a deformed portion that protrudes from the clip contact section towards the clip to form a fixed electrically conductive contact between the leadframe and the clip; and/or
wherein the leadframe contact section of the clip comprises a deformed portion that protrudes from the leadframe contact section towards the leadframe to form a fixed electrically conductive contact between the leadframe and the clip.

16. The die package arrangement of claim 15,
wherein the leadframe and the clip comprise an electroplating layer that was applied to the assembled die package arrangement.

17. A method of forming a die package, the method comprising:
attaching a die to a leadframe;
attaching a clip to the die, wherein the clip comprises a leadframe contact section that is arranged adjacent to a corresponding clip contact section of the leadframe; and
deforming the clip contact section of the leadframe and the leadframe contact section of the clip to form a fixed electrically conductive contact between the leadframe and the clip.

18. The method of claim 17, further comprising:
electroplating the leadframe and the clip after the deforming the clip contact section of the leadframe and/or the leadframe contact section of the clip; and
after the electroplating, removing the leadframe contact section of the clip and the clip contact section of the leadframe.

19. The method of claim 17,
wherein the deforming comprises pressing a portion of the clip contact section towards the clip.

20. The method of claim 17,
wherein the leadframe contact section comprises a first part and a second part that is separate from the first part;
wherein the clip contact section comprises a first part and a second part that is separate from the first part;
wherein the first part of the leadframe contact section is arranged adjacent to the first part of the clip contact section; and
wherein the second part of the clip contact section is arranged adjacent to the second part of the leadframe contact section;
wherein the deforming the clip contact section of the leadframe and the leadframe contact section of the clip comprises deforming the first part of the leadframe contact section and the first part of the clip contact section and deforming the second part of the leadframe contact section and the second part of the clip contact section;
wherein the first part of the leadframe contact section and the first part of the clip contact section form a first pair, and the second part of the leadframe contact section and the second part of the clip contact section form a second pair, and wherein the deformed portion in the first pair is performed simultaneously with the deformed portion in the second pair; and
wherein the first part of the leadframe contact section and the second part of the leadframe contact section are arranged on opposite sides of an opening in the leadframe.
